(19) United States
(12) Patent Application Publication
(10) Pub. No.: US 2014/0085844 A1
(43) Pub. Date: Mar. 27, 2014

(54) CONDUCTING MEMBER AND ELECTRONIC DEVICE PROVIDED THEREWITH

(71) Applicants: Tomofumi Katayama, Osaka-shi (JP); Hiroyuki Takebe, Osaka-shi (JP)

(72) Inventors: Tomofumi Katayama, Osaka-shi (JP); Hiroyuki Takebe, Osaka-shi (JP)

(73) Assignee: SHARP KABUSHIKI KAISHA, Osaka-shi, Osaka (JP)

(21) Appl. No.: 14/118,444

(22) PCT Filed: Jul. 27, 2012
(86) PCT No.: PCT/JP2012/069257

§ 371 Date: Nov. 18, 2013

(30) Foreign Application Priority Data
Aug. 12, 2011 (JP) 2011-177318

(51) Int. Cl. H05K 7/02

(52) U.S. Cl. CPC H05K 7/02
USPC 361/760; 439/884

(57) ABSTRACT

A conducting member (2) includes a protrusion (2a) that is flange-shaped and is provided on a side surface of the conducting member (2) which side surface is in contact with a casing (1).

### TECHNICAL FIELD

The present invention relates to a conducting member which electrically connects an inside and an outside of a casing, and to an electronic device including the conducting member.

### BACKGROUND ART

An electronic device has been widely used which includes a casing through which a conducting member passes so as to electrically connect an inside and an outside of the casing (see Patent Literatures 1 and 2).

Patent Literature 1 of these Patent Literatures describes a mobile phone including a casing into which a metallic pin is insert-molded. This is described below with reference to FIG. 6. FIG. 6, which illustrates a conventional technique, is a cross-sectional view of a relevant part of a mobile phone including a casing into which a metallic pin is insert-molded.

A mobile phone 200 includes a resin portion 203 constituting a casing of the mobile phone 200, and an insert metal plate 201 and a pin 202 each of which is insert-molded into the resin portion 203 (see FIG. 6).

According to the configuration, the insert metal plate 201 and the pin 202, which are fixed to each other, are insert-molded into the resin portion 203. Therefore, the insert metal plate 201 and a circuit and the like provided in the casing can be electrically connected by a simple configuration while the inside of the casing is airtight. Further, this allows the mobile phone to have a certain level of waterproof function. Patent Literature 1 also states that waterproofness is improved by providing a groove portion on a side surface of the pin 202 so that the pin 202 and the resin portion 203 are strongly fixed to each other.

### CITATION LIST

### Patent Literature 1

Japanese Patent Application Publication, Tokukai, No. 2010-263283 A (Publication Date: Nov. 18, 2010)

### Patent Literature 2

Japanese Patent Application Publication, Tokukai, No. 2009-66916 A (Publication Date: Apr. 2, 2009)

### SUMMARY OF INVENTION

### Technical Problem

However, it is considered that the above conventional technique may provide insufficient waterproofness. Namely, in a case where a pin is insert-molded, a small hole (a part which is not filled with a resin) may be frequently produced around the pin. Then, such a hole may make it impossible to secure waterproofness.

Particularly in a case where a pin provided with a groove portion is insert-molded, it is considered that a gap may be produced between the pin and a resin portion because a resin cannot enter the groove portion, which is narrow. Therefore, it is feared that waterproofness cannot be secured.

The present invention has been made in view of the problems, and an object of the present invention is to provide a conducting member which can more securely prevent infiltration of water into a casing, and an electronic device including the conducting member.

### Solution to Problem

In order to attain the object, a conducting member of the present invention which conducting member (i) electrically connects (a) a conducting pattern provided on an outside of a casing made of a dielectric and (b) an electronic component provided on an inside of the casing, (ii) is through the casing, and (iii) is columnar, the conducting member includes at least one protrusion that is flange-shaped and is provided on a side surface of the conducting member which side surface is in contact with the casing.

According to the configuration, at least one protrusion that is flange-shaped is provided on a side surface of the conducting member which side surface is in contact with the casing. Therefore, the configuration allows a longer length of the contact between the casing and the conducting member as compared with the conventional configuration in which no such protrusion is provided. Further, as compared with the conventional configuration in which a groove portion is provided, a configuration of the present invention in which configuration a plurality of protrusions are provided and a space between the respective plurality of protrusions is widely secured more easily allows the conducting member to have a shape which is less likely to produce a gap between the casing and the conducting member.

Therefore, according to the configuration, it is possible to more securely prevent infiltration of water or the like from the outside of the casing.

Note that the conducting member may directly connect the antenna and the circuit or may indirectly connect the antenna and the circuit via another conducting member such as a wire or the like.

In order to attain the object, an electronic device of the present invention includes: a casing: a conducting member recited in any one of claims 1 through 5 and being through the casing: the conducting pattern; and the electronic component, the electronic component and the conducting pattern being electrically connected via the conducting member.

According to the configuration, the conducting pattern and the electronic component are electrically connected via the conducting member. Therefore, water or the like is less likely to be infiltrated from the outside of the casing. That is, it is possible to provide an electronic device which includes a conducting pattern provided on an outside of a casing and is high in waterproof performance.

### Advantageous Effects of Invention

As described above, a conducting member of the present invention which conducting member (i) electrically connects (a) a conducting pattern provided on an outside of a casing made of a dielectric and (b) an electronic component provided on an inside of the casing, (ii) is through the casing, and (iii) is columnar, the conducting member includes at least one protrusion that is flange-shaped and is provided on a side surface of the conducting member which side surface is in contact with the casing.

Therefore, the configuration yields an effect of (i) allowing a longer length of the contact between the casing and the conducting member and (ii) more securely preventing infiltration of water or the like from the outside of the casing as compared with the conventional configuration in which no such protrusion is provided.

### BRIEF DESCRIPTION OF DRAWINGS

FIG. 1 schematically illustrates a configuration of a communication device of an embodiment of the present invention.

FIG. 2 shows an example of a shape of a conducting member provided in the communication device. (a) of FIG. 2 is a side view of the conducting member, (b) of FIG. 2 is a perspective view of the conducting member, and (c) of FIG. 2 is a top view of the conducting member.

FIG. 3 shows another example of the conducting member. (a) of FIG. 3 is a side view of the another example of the conducting member, (b) of FIG. 3 is a perspective view of the another example of the conducting member, and (c) of FIG. 3 is a top view of the another example of the conducting member.

FIG. 4 shows an example of a process in which a conducting pattern is provided on an outer surface of a casing of the communication device so as to be in contact with the conducting member.

FIG. 5 is a cross-sectional view of a relevant part of the communication device in which the conducting pattern is covered with a protective layer.

FIG. 6, which illustrates a conventional technique, is a cross-sectional view of a relevant part of a mobile phone including a casing into which a metallic pin is insert-molded.

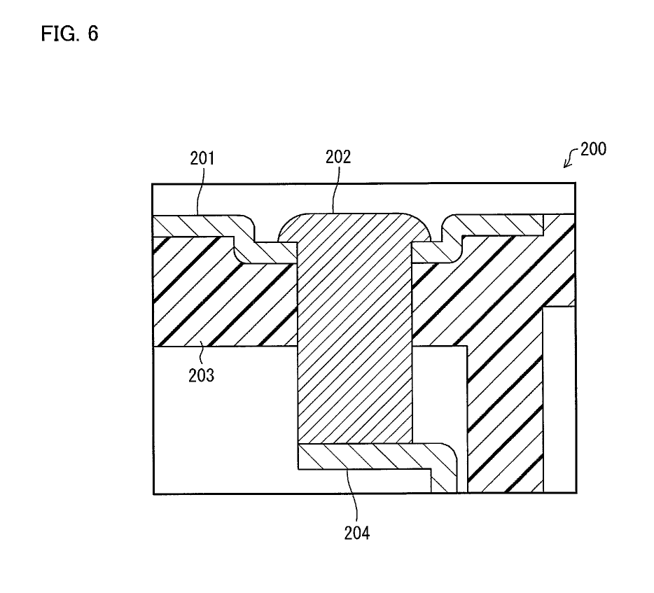

FIG. 7 illustrates other configurations studied by the inventors of the present invention so as to provide functions equivalent to that provided by the configuration in which the conducting pattern and a communication circuit of the communication device are connected via the conducting member.

### DESCRIPTION OF EMBODIMENTS

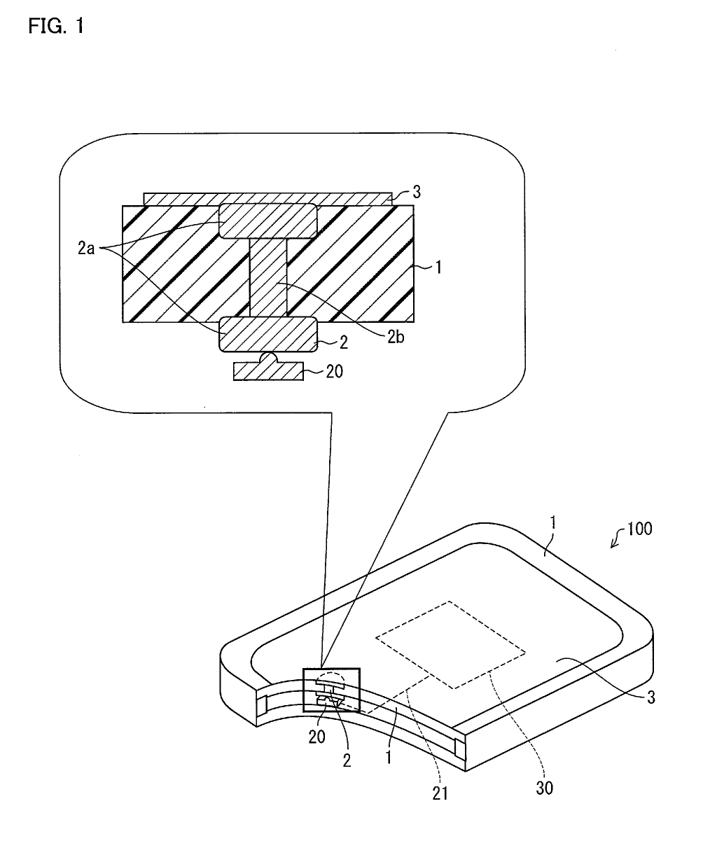

An embodiment of the present invention is specifically described below with reference to FIG. 1 through FIG. 5.

[Configuration of Communication Device]

The following description discusses, with reference to FIG. 1, a configuration of a communication device (electronic device) of an embodiment of the present invention. FIG. 1 schematically illustrates a configuration of a communication device 100. Note that FIG. 1 includes a perspective view of a cross-section of a part of the communication device 100 and a partially enlarged view of the cross-section.

The communication device 100 includes a casing 1, a conducting member 2, a conducting pattern 3, a spring terminal 20, a feed line 21, and a communication circuit (electronic component) 30 (see FIG. 1). Note that the communication device 100 has a back surface on which the conducting pattern 3 is provided and a front surface on which a display section (not illustrated) is provided. That is, the communication device 100 is a tablet communication device (e.g., a smart phone, an electronic book terminal, a tablet PC, or the like). However, the communication device 100 does not need to be such a tablet communication device provided that the communication device 100 includes a casing and has at least one of a function of receiving information from another device and a function of transmitting information to another device.

The casing 1 is made of a dielectric and forms a contour of the communication device 100. The casing 1 has an internal space in which an electronic component and the like of the communication device 100 are stored. The casing 1 is formed by connecting a front-surface-side casing and a back-surface-side casing (not illustrated). The conducting member 2 and the conducting pattern 3 are provided in the back-surface-side casing. It is only necessary that the casing be made of a non-water-permeable dielectric, and the casing 1 can be made of, for example, a resin. Note that it is only necessary that a part of the casing 1 which part is in contact with each of the conducting member 2 and the conducting pattern 3 be made of a dielectric. Therefore, all parts of the casing 1 do not need to be made of a dielectric.

The conducting member 2, which is a conducting material that is embedded in the casing 1 so as to be through the casing 1, electrically connects an inside and an outside of the casing 1. Further, it is only necessary that the conducting member 2 be electrically conductive. The conducting member 2 can be made of, for example, a metal. It is only necessary that the conducting member 2 be fixed to the casing 1. It is not limited how the conducting member is fixed to the casing. However, for example, the conducting member 2 is preferably integrally molded with the casing 1.

The conducting pattern 3 is a conducting film which is provided on the casing 1 so as to be in contact with the conducting member 2. The conducting pattern 3 is a conducting film which has no shape retention in itself (has no self shape retention). For example, the conducting pattern 3 may be a flexible conducting film such as a flexible printed circuit board or a conducting film formed by applying conducting paste.

Conducting paste, which is a viscous conducting material, at least contains metal powder and a solvent, and preferably contains metal powder, a binder resin, and a solvent. For example, according to a conducting film formed by applying conducting paste, a solvent may be removed by drying from the conducting film, or a part of the solvent may remain in the conducting film.

It is possible to employ various methods for applying conducting paste. However, conducting paste is preferably applied by printing by use of a flexible printing plate (e.g., flexsographic printing, offset printing, silk-screen printing, pad printing, or the like) so as to be suited to shapes of the casing 1 and the conducting member 2.

Note that the conducting pattern 3 is not particularly limited in shape. It is possible to appropriately set a shape of the conducting pattern 3 in accordance with, for example, design of the communication device 100. For example, the conducting pattern 3 covers an entire surface of one end of the conducting member 2 (see the example shown in FIG. 1). Alternatively, the conducting pattern 3 may have a shape which covers only a part of the one end of the conducting member 2 provided that an electric connection between the conducting pattern 3 and the conducting member 2 is sufficiently maintained.

The other end of the conducting member 2 is electrically connected with the spring terminal 20, which is provided in the casing 1 and presses the conducting member 2 in a direction from the inside toward the outside of the casing 1. The spring terminal 20 is electrically connected with the communication circuit 30 via the feed line 21.

According to the communication device 100, the conducting pattern 3, which is fed by the communication circuit 30 via the conducting member 2, the spring terminal 20, and the feed line 21, operates as an antenna. In this case, the other end of the conducting member 2 which end is connected with the spring terminal 20 serves as an electrode to be connected with the feed line 21 via which the conducting pattern 3 is fed.

[Configuration and Main Characteristics of Conducting Member]

The conducting member 2 has an axial part 2b and protrusions 2a provided at both ends of the axial part 2b (see the enlarged cross-sectional view of FIG. 1). The conducting member 2 which has the protrusions 2a allows a larger area of a contact between the casing 1 and the conducting member 2 as compared with the conducting member 2 which has no protrusions 2a. This makes it possible to stably fix the conducting member 2 in the casing 1.

Further, a length of the contact between the casing 1 and the conducting member 2 can be long. This prevents easy infiltration of water into the casing from a gap between the casing 1 and the conducting member 2. That is, the conducting member 2 which has the protrusions 2a allows the communication device 100 to increase waterproof performance.

Note that the conducting member 2 which has the protrusions 2a at both ends thereof (see the example shown in FIG. 1) allows a larger area of a contact between the conducting member 2 and each of the conducting pattern 3 and the spring terminal 20 as compared with the conducting member 2 which has no protrusions 2a. This allows a more secure electric connection between the conducting member 2 and each of the conducting pattern 3 and the spring terminal 20.

Note that an end surface of one of the protrusions 2a which end surface is in contact with the conducting pattern 3 may be flat. However, the end surface is preferably rough. The end surface which is rough allows a stronger connection between the one of the protrusions 2a and the conducting pattern 3.

Further, the end surface of the one of the protrusions 2a which end surface is in contact with the conducting pattern 3 is flush with an outer surface of the casing 1 (a surface of the casing 1 on which surface the conducting pattern 3 is provided) (see the example shown in FIG. 1). This causes the conducting pattern 3 to be even and planar. Note, however, that the end surface of the one of the protrusions 2a which end surface is in contact with the conducting pattern 3 may protrude from or sink below the outer surface of the casing 1 provided that the end surface has no influence on performance of the conducting pattern 3.

Note that an end of the other of the protrusions 2a which end is in contact with the spring terminal 20 protrudes from an inner surface of the casing 1 (a surface of the casing 1 which surface faces away from the surface on which the conducting pattern 3 is provided) (see the example shown in FIG. 1). This is because the casing 1 is formed by insert molding by fixing the end in a mold. However, the end may be flush with the inner surface of the casing 1 or sink below the inner surface of the casing 1.

The protrusions 2a, which are identical in shape, are provided at both ends of the axial part 2b, which is cylindrical (see the example shown in FIG. 1). Therefore, the conducting member 2 has a shape which is in plane symmetry with a plane that bisects the conducting member 2 in a transverse direction of FIG. 1 (a plane in parallel with end surfaces of the protrusions 2a). In other words, the conducting member 2 has a shape which is in 180° rotation symmetry with a straight line which is in parallel with the end surfaces of the protrusions 2a and passes through a central axis of the axial part 2b.

According to this, during a process for producing the communication device 100, a direction in which the conducting member 2 is provided is less restricted in a step (insert molding step) of fixing the conducting member 2 in a mold and then pouring a resin into the mold so as to integrally mold the casing 1 and the conducting member 2.

This is because, also in a case where a direction in which the conducting member 2 is fixed in the mold is reversed by 180°, the conducting pattern 3 and the communication circuit 30 are similarly electrically connected. For example, the conducting member 2 may be fixed in the mold so that a first end surface of the conducting member 2 which first end surface is in contact with the conducting pattern 3 is in contact with the spring terminal 20 and a second end surface of the conducting member 2 which second end surface is in contact with the spring terminal 20 is in contact with the conducting pattern 3. Note that, also in the case where a direction in which the conducting member 2 is fixed in the mold is reversed by 180°, the symmetry (described earlier) of the conducting member 2 may collapse provided that the conducting pattern 3 and the communication circuit 30 are similarly electrically connected. For example, one and the other of the protrusions 2a may have respective planar and convex ends provided that the conducting pattern 3 and the communication circuit 30 are similarly electrically connected.

Note here that the conducting member 2 is directly connected with the conducting pattern 3 and is indirectly connected with the communication circuit 30 via the spring terminal 20 and the feed line 21 (see the example shown in FIG. 1). However, it is not limited to this example how the conducting member 2 is connected with each of the conducting pattern 3 and the communication circuit 30. Namely, the conducting member 2 may be indirectly connected with the conducting pattern 3 via another conducting member or may be directly connected with the communication circuit 30 by, for example, providing the communication circuit 30 directly below the conducting member 2. Note that the indirect connection includes a connection in which no direct current flows. For example, the indirect connection includes a method for capacitively coupling the conducting member 2 and the conducting pattern 3 by providing a sheet or the like between the conducting member 2 and the conducting pattern 3.

The conducting member 2 illustrated in FIG. 1 has a shape which is in line symmetry with the central axis of the axial part 2b. Therefore, no phase difference occurs between, both ends of the conducting member 2 regardless of through which path on the conducting member 2 an electric current flowing through the conducting member 2 passes. This allows the conducting pattern 3 to have a stable antenna characteristic.

[Shape of Conducting Member]

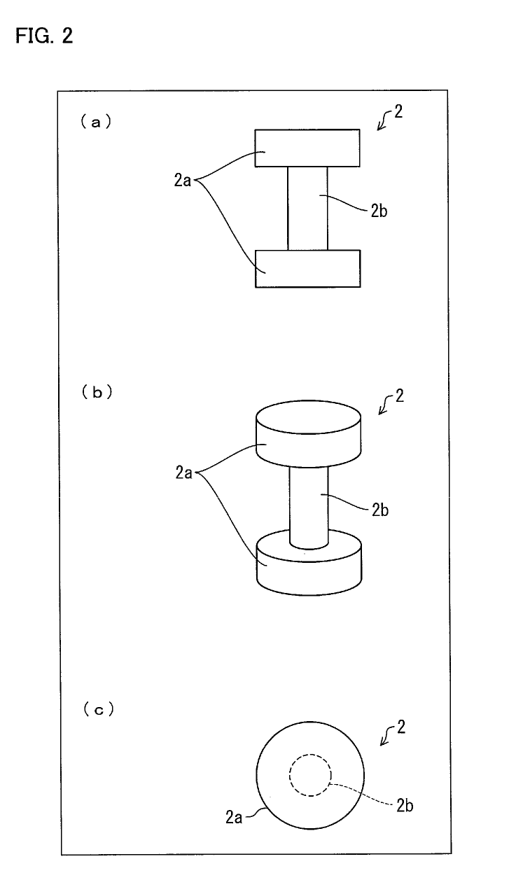

A shape of the conducting member 2 is more specifically described below with reference to FIG. 2. FIG. 2 shows an example of the shape of the conducting member 2. (a) of FIG. 2 is a side view of the conducting member 2, (b) of FIG. 2 is a perspective view of the conducting member 2, and (c) of FIG. 2 is a top view of the conducting member 2. Note that an elevation view, a rear view, a right side view, and a left side view of the conducting member 2 illustrated in FIG. 2 are each identical to (a) of FIG. 2 and a bottom view of the conducting member 2 illustrated in FIG. 2 is identical to (c) of FIG. 2.

The conducting member 2 has the protrusions 2a provided at both ends of the axial part 2b, which is cylindrical, and is pin-shaped (see (a) through (c) of FIG. 2). According to this, the conducting member 2 has an “I” shape when seen from the side. Note that the protrusions 2a and the axial part 2b are names implying parts of the conducting member 2 and do not mean that the protrusions 2a and the axial part 2b are separate members.

Each of the protrusions 2a is a flange-shaped part which protrudes from a side surface of the axial part 2b. A protrusion 2a illustrated in FIG. 2 has a cylindrical shape. One of a top surface or a bottom surface of the protrusion 2a serves as a part which is in contact with the conducting pattern 3 or the spring terminal 20, and a central part of the other of the top surface or the bottom surface of the protrusion 2a is in contact with the axial part 2b. Note that the protrusion 2a has a height (height between the top surface and the bottom surface) lower than that of the axial part 2b (see the example shown in FIG. 2). However, setting of the heights of the protrusion 2a and the axial part 2b is not limited to this.

Note that the protrusions 2a are provided so that the length of the contact between the casing 1 and the conducting member 2 is as long as possible. It is only necessary that the protrusions 2a have shapes which cause the conducting member 2 provided with the protrusions 2a to have a longer length of the contact with the casing 1 as compared with the conducting member 2 provided with no protrusions 2a. The shapes of the protrusions 2a are not limited to those of the example shown in FIG. 2. Note also that the shapes of the protrusions 2a at both ends of the conducting member 2 may be different from each other. For example, heights of the protrusions 2a may be different from each other. That is, one of the protrusions 2a may be thicker than that of the other of the protrusions 2a.

For example, the protrusion 2a may have a prism shape or be in asymmetry with its central axis (for example, the top surface and the bottom surface of the protrusion 2a are elliptical). Alternatively, the protrusion 2a may have a trapezoidal shape (a shape corresponding to a part of a circular cone) in the side view of the conducting member 2. Further, the central axes of the axial part 2b and the protrusion 2a coincide with each other (see the example shown in FIG. 2). However, the central axes do not need to coincide with each other.

Note that, in order to carry out secure waterproofing, it is desirable that the protrusions 2a have shapes which cause the conducting member 2 provided with the protrusions 2a to have a length of the contact with the casing 1 (a length of a part of the conducting member 2, which part is in contact with the casing 1, of a line segment which connects both ends of the conducting member 2 by the shortest distance) which length is not less than 1.2 times longer than that of the conducting member 2 provided with no protrusions 2a. It is empirically known that the conducting member 2 whose protrusions have such shapes as described above can yield a more satisfactory waterproof effect as compared with the conventional example.

In a case where the conducting member 2 is insert-molded into the casing 1, if surfaces of the protrusions 2a which surfaces face each other are in too close vicinity to each other, a problem occurs such that a part which is not filled with a resin may be produced between the protrusions 2a. Therefore, the protrusions 2a are preferably provided at a distance which does not cause the problem. This is because, though the resin is filled from a vicinity of the conducting member 2 toward a space between the protrusions 2a while the conducting member 2 is being insert-molded into the casing 1, insufficient filling (short shot) occurs in a case where the space between the protrusions 2a is too narrow with respect to a thickness of the resin in the vicinity of the conducting member 2. Though depending on, for example, viscosity of the resin, experience of the inventors of the present invention shows that the distance between the protrusions 2a is preferably 0.2 mm or more in a case where a normal ABS resin is used as the resin.

The axial part 2b, which has a cylindrical shape, is connected with the protrusions 2a on respective end surfaces thereof. It is only necessary that the axial part 2b have a columnar shape which allows the protrusions 2a to be connected with both ends of the axial part 2b. The axial part 2b may have not only the cylindrical shape but also a prism shape. Further, the axial part 2b does not need have a uniform thickness.

In view of the above, it is only necessary that the shapes of the protrusions 2a and the axial part 2b allow the conducting member 2 integrally molded with the casing 1 to connect the conducting pattern 3 and the spring terminal 20. Further, it is only necessary that the conducting member 2 provided with the protrusions 2a cause the length of the contact between the casing 1 and the conducting member 2 to be longer as compared with the conducting member 2 provided with no protrusions 2a.

Therefore, for example, either one or both of the protrusions 2a may be provided at a place other than the end(s) of the axial part 2b. Alternatively, the conducting member 2 may have a shape such that only one protrusion 2a is provided at any place on the axial part 2b.

However, the conducting member 2 may have a shape which causes no phase difference between both ends of the conducting member 2 regardless of through which path on the conducting member 2 an electric current flowing through the conducting member 2 passes. Specifically, it is preferable that the conducting member 2 have a shape which is in line symmetry with the central axis (an axis connecting a center of the top surface and a center of the bottom surface) (the conducting member 2 have a cross-section whose shape is in line symmetry with the central axis, the cross-section being obtained by cutting the conducting member 2 along any plane that is through the central axis). In other words, it is preferable that shapes of the conducting member 2 coincide with each other before and after the conducting member 2 rotates on the central axis by any angle.

This is because of the following reason. A high-frequency electric current which is used for an antenna is transmitted through a surface of the conducting member 2 by a skin effect. Therefore, depending on a shape of a surface of the conducting member 2, a phase difference is caused by a path through which the high-frequency electric current is conducted. This prevents the conducting pattern 3 from having a stable antenna characteristic.

Further, it is preferable that the conducting member 2 have a shape which is in plane symmetry with a plane that bisects the conducting member 2 in a transverse direction of FIG. 2 (a plane in parallel with the end surfaces of the protrusions 2a). In other words, it is preferable that the conducting member 2 have a cross-section whose shape is in line symmetry with a straight line which is orthogonal to the central axis and is located at equal distances from both ends of the conducting member 2, the cross-section being obtained by cutting the conducting member 2 along any plane that is through the central axis. The reason is that according to this, a direction in which the conducting member 2 is provided is less restricted in the insert molding step during the process for producing the communication device 100.

[Another Example of Conducting Member]

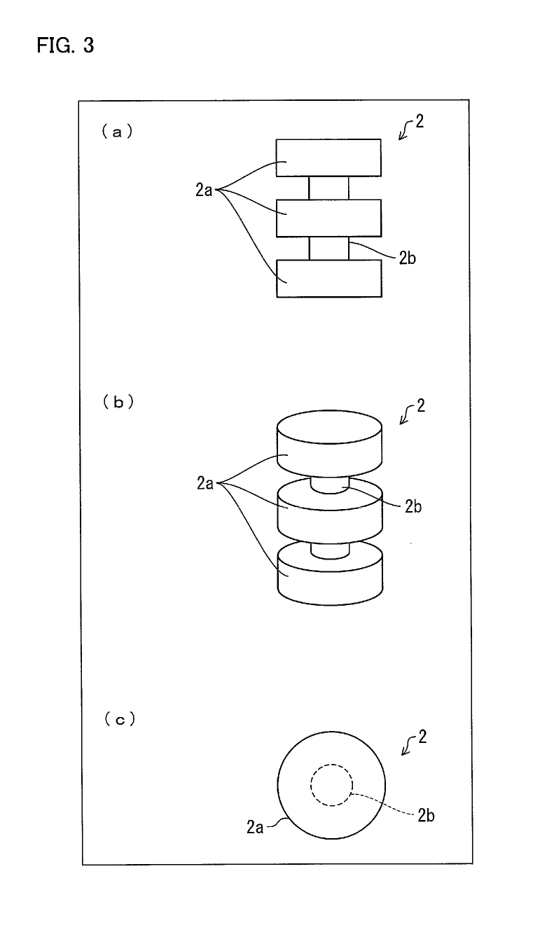

Another example of the conducting member 2 is more specifically described below with reference to FIG. 3. FIG. 3 shows the another example of the conducting member 2. (a) of FIG. 3 is a side view of the another example of the conducting member 2, (b) of FIG. 3 is a perspective view of the another example of the conducting member 2, and (c) of FIG. 3 is a top view of the another example of the conducting member 2. Note that as in the case of the conducting member 2 illustrated in FIG. 2, an elevation view, a rear view, a right side view, and a left side view of the conducting member 2 illustrated in FIG. 3 are each identical to (a) of FIG. 3 and a bottom view of the conducting member 2 illustrated in FIG. 3 is identical to (c) of FIG. 3.

The conducting member 2 of FIG. 3 is different from the example of the conducting member 2 of FIG. 2 in that the conducting member 2 of FIG. 3 is provided with another protrusion 2a. Specifically, the axial part 2b has, at both ends thereof, the protrusions 2a having a configuration identical to that of the protrusions 2a of FIG. 2. The axial part 2b further has one protrusion 2a provided between the protrusions 2a provided at both ends of the axial part 2b. According to this, the conducting member 2 has a shape like the Chinese character “ +̅” when seen from the side.

The example of the conducting member 2 of FIG. 3 has a longer length of the contact with the casing 1 as compared with the example of the conducting member 2 of FIG. 2. This allows a further increase in waterproof performance. Note that the protrusion 2a in the middle is located at equal distances from the protrusions 2a provided at both ends of the axial part 2b. However, the protrusion 2a in the middle may be located so as to be closer to either one of the protrusions 2a provided at both ends of the axial part 2b. Further, the conducting member 2 may have four or more protrusions 2a.

[Process for Producing Communication Device]

The process for producing the communication device 100 includes: a first step of forming the casing 1 in which the conducting member 2 is embedded; and a second step, following the first step, of providing the conducting pattern 3 on the outer surface of the casing 1 so that the conducting pattern 3 is in contact with the conducting member 2.

For example, the conducting member 2 and the casing 1 may be integrally molded in the first step. Namely, the integral molding (insert molding) can be carried out by fixing, in the mold for molding the casing 1, the conducting member 2, which has been formed in advance, filling, after closing the mold, the mold with a dielectric material of which the casing 1 is made, and then solidifying the dielectric material.

Note that the conducting member 2 may be embedded in the casing 1 by inserting the conducting member 2 into the casing 1 thus formed. In this case, it is preferable that, after the conducting member 2 which has a protrusion 2a at only one end thereof is embedded in the casing 1, a protrusion 2a be formed at the other end of the conducting member 2 by, for example, thermal caulking. Alternatively, protrusions 2a may be formed at both ends of the conducting member 2 by a similar method after the conducting member 2 which has no protrusions 2a at both ends thereof is embedded in the casing 1.

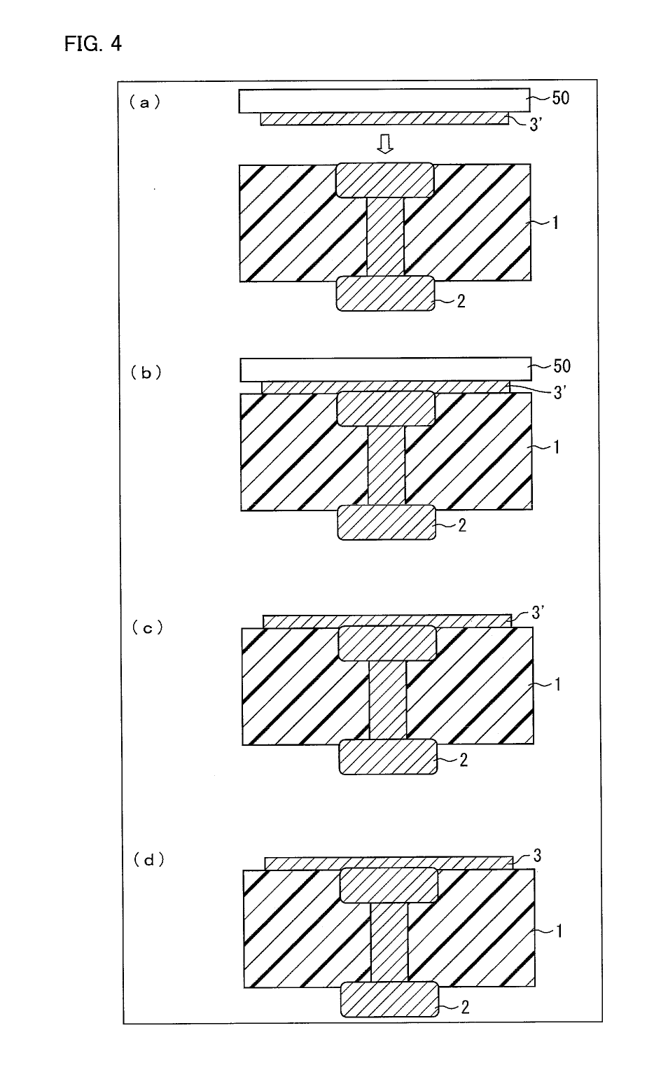

For example, the conducting pattern 3 may be formed in the second step by forming a desired pattern by application of conducting paste to the outer surface of the casing 1, and then subjecting the conducting paste to, for example, drying. It is possible to employ various methods for applying conducting paste. However, conducting paste is preferably applied by printing by use of a flexible printing plate (e.g., flexsographic printing, offset printing, silk-screen printing, pad printing, or the like). This is described below with reference to FIG. 4.

FIG. 4 shows an example of a process in which the second step is carried out. First, a printing plate 50 having a surface on which a desired pattern is formed in advance by use of conducting paste 3′ is made closer to the outer surface (including a part on which the conducting member 2 is exposed) of the casing 1 formed in the first step (see (a) of FIG. 4). Then, the printing plate 50 is pressed against the outer surface of the casing 1 (see (b) of FIG. 4), so that a pattern of the conducting paste 3′ is transferred onto the outer surface of the casing 1 (see (c) of FIG. 4).

Thereafter, the conducting pattern 3 can be formed by drying the pattern of the conducting paste 3′ (see (d) of FIG. 3). Note that it is possible to use a silk-screen printing method in which the conducting paste 3′ is pressed out of a hole provided in the printing plate 50.

Further, the conducting pattern 3 which is constituted by a flexible printed circuit board can be formed by attaching the flexible printed circuit board to the outer surface of the casing 1.

[Protection of Conducting Pattern]

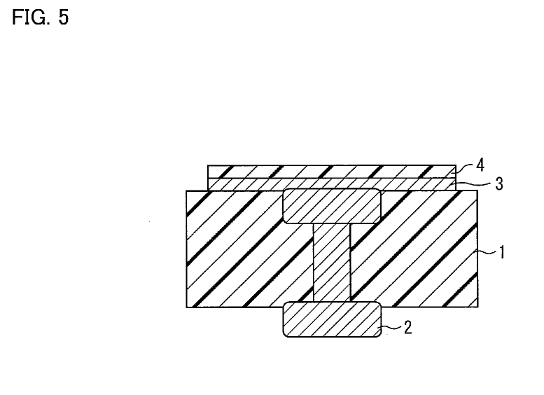

The conducting pattern 3 is exposed on the casing 1 according to the example shown in FIG. 1. However, it is preferable that the conducting pattern 3 be protected by providing a protective layer or the like. This is described below with reference to FIG. 5. FIG. 5 is a cross-sectional view of a relevant part of the communication device 100 in which the conducting pattern 3 is covered with a protective layer.

In a case where the communication device 100 further includes a protective layer 4 provided on the conducting pattern 3, it is possible to prevent the conducting pattern 3 from being damaged (see FIG. 5). It is only necessary that a step of forming the protective layer 4 be carried out after the step, shown in FIG. 4, of forming the conducting pattern 3.

Note that it is only necessary that the protective layer 4 (i) be made of a material which does not affect antenna performance and (ii) be strong enough to protect the conducting pattern 3. Note here that “does not affect antenna performance” means that antenna performance does not greatly deteriorate depending on presence of the protective layer 4. For example, a protective layer made of a coating agent (e.g., a resin solution) can be suitably used as the protective layer 4. Application of the coating agent may also serve as coating of the casing 1. Further, it is also possible to protect the conducting pattern 3 by attaching a sheet material such as PET as the protective layer 4 to the conducting pattern 3, or pressing the sheet material as the protective layer 4 on the conducting pattern 3 by heat or pressure.

[Comparison with Other Configurations]

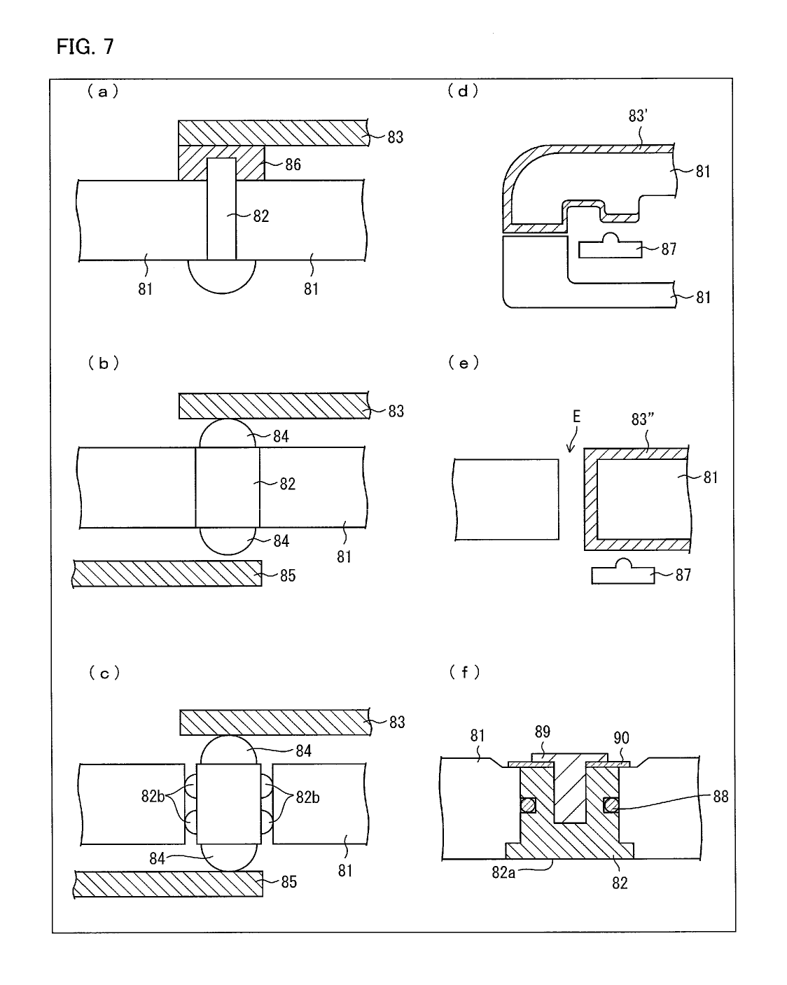

The inventors of the present invention studied various configurations before accomplishing a configuration in which the conducting pattern 3 and the communication circuit 30 of the communication device 100 are connected via the conducting member 2. This is described below with reference to FIG. 7. FIG. 7 illustrates other configurations studied by the inventors of the present invention so as to provide functions equivalent to that provided by the configuration in which the conducting pattern 3 and the communication circuit 30 of the communication device 100 are connected via the conducting member 2.

(a) of FIG. 7 illustrates a configuration in which a conducting pin 82 protrudes by being through a resin part (corresponding to the casing 1) and a protruding part thereof adheres to a metal plate 83 via an adhesive 86 which is electrically conductive. According to the configuration, the adhesive 86 needs to have (i) a thickness for covering the protruding part and (ii) a volume for obtaining a strength for fixing the resin part 81 and the metal plate 83. This causes a problem of difficulty in slimming down.

(b) of FIG. 7 illustrates a configuration in which the conducting pin 82 which is embedded in the resin part 81 is connected via a pogo pin 84 with each of the metal plate 83 and a metal plate 85 (the conducting pin 82 may be connected with the metal plate 85 via a protrusion instead of the pogo pin). According to the configuration, the metal plate 83 needs to be thick so as to have stiffness which prevents the metal plate 83 from being bent by the pogo pin 84. This causes a problem of difficulty in slimming down.

(c) of FIG. 7 and (b) of FIG. 7 are substantially identical in configuration but differ in that the conducting pin 82 has protrusions 82b on side surfaces thereof so as to compress the protrusions 82b into the resin part 81. The configuration illustrated in (c) of FIG. 7 has not only a problem identical to that of the configuration illustrated in (b) of FIG. 7 but also a problem such that waterproofness is lost in a space between the resin part 81 and the conducting pin 82.

(d) of FIG. 7 illustrates a configuration in which a conducting section 83′ is led from an outside via a side surface to an inside of the resin part 81 so as to be connected with a spring terminal 87. According to the configuration, in a case where the conducting section 83′ is formed by printing or an LDS (Laser Direct Structure), the conducting section 83′ and the spring terminal 87 are easily disconnected from each other in a folded part of the conducting section 83′. Meanwhile, in a case where the conducting section 83′ is formed by an MID (Molded Interconnect Device), waterproofness is lost in a part of the conducting section 83′ in which part the conducting section 83′ is led into the casing. Further, a fitting part of the resin part 81 generally has a complicated structure. This may cause the conducting section 83′ to have a complicated shape or may prevent the conducting section 83′ from being provided. Even if the conducting section 83′ can be provided, the conducting section 83′ needs to be routed for a long distance. This may cause a deterioration in performance of the conducting section 83′ in a case where the conducting section 83′ is used as an antenna.

(e) of FIG. 7 illustrates a configuration in which the resin part 81 is provided with an opening E and a flexible printed circuit board 83″ is through the opening E. For example, the configuration have many restrictions on shape such as a restriction on a place at which a feeding point is provided in a case where the flexible printed circuit board 83″ is used as an antenna. Further, according to the configuration, waterproof performance is also impaired.

(f) of FIG. 7 illustrates a configuration in which the conducting pin 82 is embedded in the resin part 81, nut metal plates 90 are fixed by a screw 89 on the appearance side of the resin part 81, and for example, a spring mounted on a substrate is connected with an inside surface 82a of the conducting pin 82. Note that waterproof rings 88 may be provided between side walls of the resin part 81 and the conducting pin 82. Formation of the configuration requires tightening-together, caulking, or adhesion (a gasket, a conducting binding material, a conducting tape, or the like). Therefore, the nut metal plates 90 need to have a sufficient strength. This causes a deterioration in degree of freedom of shape of the nut metal plates 90.

As described earlier, the configuration of the present embodiment in which configuration the conducting pattern 3 and the communication circuit 30 of the communication device 100 are connected via the conducting member 2 yields a more advantageous effect than the configurations illustrated in (a) through (f) of FIG. 7.

[Additional Descriptions]

As described earlier, a conducting member of the present invention which conducting member (i) electrically connects (a) a conducting pattern provided on an outside of a casing made of a dielectric and (b) an electronic component provided on an inside of the casing, (ii) is through the casing, and (iii) is columnar, the conducting member includes at least one protrusion that is flange-shaped and is provided on a side surface of the conducting member which side surface is in contact with the casing.

According to the configuration, at least one protrusion that is flange-shaped is provided on a side surface of the conducting member which side surface is in contact with the casing. Therefore, the configuration allows a longer length of the contact between the casing and the conducting member as compared with the conventional configuration in which no such protrusion is provided. Further, as compared with the conventional configuration in which a groove portion is provided, a configuration of the present invention in which configuration a plurality of protrusions are provided and a space between the respective plurality of protrusions is widely secured more easily allows the conducting member to have a shape which is less likely to produce a gap between the casing and the conducting member.

Therefore, according to the configuration, it is possible to more securely prevent infiltration of water or the like from the outside of the casing.

Note that the conducting member may directly connect the antenna and the circuit or may indirectly connect the antenna and the circuit via another conducting member such as a wire or the like.

The conducting member is preferably configured such that: the conducting member is integrally molded with the casing by filling, with a resin, a mold in which the conducting member is fixed, the casing being made of the resin; and the conducting member has a shape which allows the electric connection between the conducting pattern and the electronic component also in a case where the conducting member is fixed in the mold in a reversed direction.

According to the configuration, the conducting member has a shape which allows the electric connection between the conducting pattern and the electronic component also in a case where the conducting member is fixed in the mold in a reversed direction. Therefore, a direction in which the conducting member and the casing are integrally molded is less restricted. According to this, during a process for producing a communication device including the conducting member, it is unnecessary, in a step of integrally molding the casing and the conducting member, to determine in which direction the conducting member is fixed in the mold.

The conducting member is preferably configured such that the conducting member has a shape which causes no phase difference between both ends of the conducting member which are connected with the conducting pattern and the electronic component, respectively, regardless of through which path on the conducting member an electric current flowing between the both ends passes.

According to the configuration, the conducting member has a shape which causes no phase difference between both ends of the conducting member which are connected with the conducting pattern and the electronic component, respectively, regardless of through which path on the conducting member an electric current flowing between the both ends passes. Therefore, also in a case where the conducting member is provided with a protrusion, an electric current can flow between the conducting pattern and the electronic component in a stable phase.

Note that, in a case where the conducting member has a shape which causes no phase difference between both ends of the conducting member, it is only necessary, for example, that a shape of a surface of the conducting member be in line symmetry with a central axis of a columnar part of the conducting member. In other words, it is only necessary that the surface of the conducting member have a shape which causes no change in appearance of the conducting member after the conducting member rotates on the central axis by any angle.

The conducting member is preferably configured such that the at least one protrusion includes protrusions provided at the respective both ends.

According to the configuration, the at least one protrusion includes protrusions provided at the respective both ends. This allows an increase in area of a contact of each of the both ends with the conducting pattern or the electronic component (or area of a contact of each of the both ends with a wire or the like which is connected with the conducting pattern or the electronic component). Therefore, the conducting pattern and the electronic component can be electrically connected more securely.

The conducting member is preferably configured to further include at least one protrusion provided between the protrusions provided at the respective both ends.

According to the configuration, the conducting member includes at least three protrusions. This allows a further increase in waterproof performance by making longer a length of the contact between the casing and the conducting member.

As described earlier, an electronic device of the present invention includes: a casing: a conducting member recited in any one of claims 1 through 5 and being through the casing: the conducting pattern; and the electronic component, the electronic component and the conducting pattern being electrically connected via the conducting member.

According to the configuration, the conducting pattern and the electronic component are electrically connected via the conducting member. Therefore, water or the like is less likely to be infiltrated from the outside of the casing. That is, it is possible to provide an electronic device which includes a conducting pattern provided on an outside of a casing and is high in waterproof performance.

The electronic device is preferably configured such that the conducting pattern is formed by applying conducting paste to an outer surface of the casing.

According to the configuration, the conducting pattern is formed by applying conducting paste. Therefore, also in a case where the conducting member protrudes from or sinks below a surface of the casing, the conducting pattern and the conducting member are directly connected. That is, according to the configuration, the conducting pattern and the conducting member can be securely and strongly connected via no other wire or the like regardless of a degree of exposure of the conducting member.

Further, during production of the electronic device having the configuration, it is possible to form a conducting pattern such as a fine pattern or a curved pattern which is difficult to form by use of a metal plate. This brings about an advantage of increasing freedom of design.

The electronic device is preferably configured such that the conducting pattern is formed by applying the conducting paste to the outer surface of the casing by printing by use of a flexible printing plate.

According to the configuration, the conducting pattern is formed by printing by use of a flexible printing plate. According to this, also in a case where a surface of the casing on which surface the conducting pattern is formed (including a part in which the conducting member is exposed) is slightly uneven, the conducting pattern and the conducting member can be securely and strongly connected via no other wire or the like. Further, the configuration brings about an advantage such that conducting patterns can be efficiently formed for many casings during the production process.

The electronic device is preferably configured to further include a protective layer provided on the conducting pattern.

According to the configuration, a protective layer can prevent an applied conducting material (conducting pattern) from coming off. Note that it is only necessary that the protective layer (i) be made of a material which does not affect antenna performance and (ii) be strong enough to protect the conducting material. Note here that “does not affect antenna performance” means that antenna performance does not greatly deteriorate depending on presence of the protective layer 4.

For example, the protective layer may be formed by coating with paint containing a resin or the like. Alternatively, the protective layer may also be formed by attaching a sheet material such as PET to the conducting material, or pressing the sheet material on the conducting material by heat or pressure. In the case of coating with paint, paint with which the casing is coated also serves as the protective layer. Therefore, such a case allows a simpler process for producing an electronic device as compared with a case where formation of a protective layer is carried out separately from painting.

The present invention is not limited to the description of the embodiments above, but may be altered within the scope of the claims. An embodiment based on a proper combination of technical means appropriately altered within the scope of the claims is encompassed in the technical scope of the present invention.

### INDUSTRIAL APPLICABILITY

The present invention is usable for an electronic device including a conducting member which electrically connects an inside and an outside of a casing.

### REFERENCE SIGNS LIST

1 Casing
2 Conducting member
2a Protrusion
2b Axial part
3 Conducting pattern
4 Protective layer
30 Communication circuit (Electronic component)
50 Printing plate
100 Communication device (Electronic device)

1-14. (canceled)

15. A conducting member which (i) electrically connects (a) a conducting pattern provided on an outside of a casing made of a dielectric and (b) an electronic component provided on an inside of the casing, (ii) is through the casing, and (iii) is columnar,
said conducting member comprising at least one protrusion that is flange-shaped and is provided on a side surface of the conducting member which side surface is in contact with the casing.

16. The conducting member as set forth in claim 15, wherein:
the conducting member is integrally molded with the casing by filling, with a resin, a mold in which the conducting member is fixed, the casing being made of the resin; and
the conducting member has a shape which allows the electric connection between the conducting pattern and the electronic component also in a case where the conducting member is fixed in the mold in a reversed direction.

17. The conducting member as set forth in claim 15, wherein the conducting member has a shape which causes no phase difference between both ends of the conducting member which are connected with the conducting pattern and the electronic component, respectively, regardless of through which path on the conducting member an electric current flowing between the both ends passes.

18. The conducting member as set forth in claim 15, wherein the at least one protrusion comprises protrusions provided at the respective both ends.

19. The conducting member as set forth in claim 18, further comprising at least one protrusion provided between the protrusions provided at the respective both ends.

20. An electronic device comprising:
a casing:
a conducting member recited in claim 15 and being through the casing:
the conducting pattern; and
the electronic component,
the electronic component and the conducting pattern being electrically connected via the conducting member.

21. The electronic device as set forth in claim 20, wherein the conducting pattern is formed by applying conducting paste to an outer surface of the casing.

22. The electronic device as set forth in claim 21, wherein the conducting pattern is formed by applying the conducting paste to the outer surface of the casing by printing by use of a flexible printing plate.

23. The electronic device as set forth in claim 21, further comprising a protective layer provided on the conducting pattern.

24. An electronic device comprising:
a casing:
a conducting member recited in claim 18 and being through the casing:
the conducting pattern; and
the electronic component,
the conducting member being electrically connected with the electronic component via an end surface of one of the protrusions provided at the respective both ends of the conducting member, and the conducting member being electrically connected with the conducting pattern via an end surface of the other of the protrusions provided at the respective both ends of the conducting member.

25. The conducting member recited in claim 15, wherein the conducting member is in plane symmetry with a plane that bisects the conducting member in a direction of a central axis of the conducting member and is orthogonal to the central axis.

26. The conducting member recited in claim 15, wherein the conducting member is in rotation symmetry with respect to the central axis of the conducting member.

27. The conducting member recited in claim 15, wherein the at least one protrusion is provided so as to be apart from the both ends.

28. The conducting member recited in claim 15, wherein an end surface of one of the at least one protrusion which end surface is in contact with the conducting pattern is rough.
